(19) United States
(12) Patent Application Publication
(10) Pub. No.: US 2018/0007798 A1
(43) Pub. Date: Jan. 4, 2018

(54) MOUNTING SUBSTRATE MANUFACTURING APPARATUS AND METHOD OF MANUFACTURING MOUNTING SUBSTRATE

(71) Applicant: Sharp Kabushiki Kaisha, Sakai City, Osaka (JP)

(72) Inventors: KATSUHIRO YAMAGUCHI, Sakai City (JP); NOBUHIRO NAKATA, Sakai City (JP); YUKINORI MASUDA, Sakai City (JP); TOMOKI TAKAHARA, Sakai City (JP)

(21) Appl. No.: 15/542,999

(22) PCT Filed: Jan. 7, 2016
(86) PCT No.: PCT/JP2016/050297

§ 371 Date: Jul. 12, 2017

(30) Foreign Application Priority Data
Jan. 14, 2015 (JP) 2015-005071

(51) Int. Cl. H05K 3/36; H05K 1/14; G02F 1/1345

(52) U.S. Cl. CPC H05K 3/361; H05K 1/144; H05K 2201/056; G02F 1/13452; H05K 2201/10136; H05K 2201/041

(57) ABSTRACT

A mounting substrate manufacturing apparatus includes a first FPC-side pressing member 51 configured to press and heat a first mounting component group 31 including one edge side mounting component that is a flexible printed circuit board 13 arranged on one edge in an arrangement direction in which flexible printed circuit boards 13 arranged on an array substrate 11B and thermally press and bond the first mounting component group 31 on the array substrate 11B, and a second FPC-side pressing member 52 arranged next to the first FPC-side pressing member 51 in the arrangement direction and configured to press and heat a second mounting component group 32 including all the flexible printed circuit boards 13 except for the first mounting component group 31 and thermally press and bond the second mounting component group 32 on the array substrate 11B.

### TECHNICAL FIELD

The present invention relates to a mounting substrate manufacturing apparatus and a method of manufacturing a mounting substrate.

### BACKGROUND ART

An example of apparatuses of manufacturing panel substrates is disclosed in Patent Document 1. In the manufacturing apparatus of patent Document 1, TCP is thermally pressed and bonded on the terminal portions of the panel substrate with a pressing head.

### RELATED ART DOCUMENT

### Patent Document

Patent Document 1: Japanese Unexamined Patent Application Publication No. 2011-3646

### Problem to be Solved by the Invention

According to increase in the density of the mounting circuit, the number of terminals mounted on the panel substrate is increased and the pressing head is likely to be longer. As the pressing head is longer, thermal strain is likely to be caused in the pressing head by heat of the thermal pressing. As the pressing head is longer, it may be difficult to adjust a pressing surface of the pressing head to be parallel to a surface of the panel substrate or replace the pressing head.

### DISCLOSURE OF THE PRESENT INVENTION

The present invention was made in view of the above circumstances. An object is to provide a mounting substrate manufacturing apparatus in which a heating member for performing thermal compression bonding is less likely to be elongated. Another object is to provide a method of manufacturing a mounting substrate with which a heating member for performing thermal compression bonding is less likely to be elongated.

### Means for Solving the Problem

A mounting substrate manufacturing apparatus according to the present technology includes a first heating member configured to press and heat a first mounting component group including one edge side mounting component that is arranged on one edge in an arrangement direction in which mounting components are arranged on a substrate and thermally press and bond the first mounting component group on the substrate, and a second heating member arranged next to the first heating member in the arrangement direction and configured to press and heat a second mounting component group including all the mounting components except for the first mounting component group and thermally press and bond the second mounting component group on the substrate.

According to the present technology, the mounting components are thermally pressed by the two heating members (the first heating member and the second heating member). Therefore, compared to a configuration in which the mounting components are collectively and thermally pressed with one heating member, each of the pressing members has a smaller length and thermal strain is less likely to be caused in the heating member when heating. Compared to a configuration including heating members in a same number of the mounting components, the total number of the heating members is smaller and the number of spaces between the adjacent heating members is also smaller. To surely thermally press and the bond the mounting components, each heating member is necessary to be arranged such that the space between the adjacent heating members is not overlapped with the mounting component. According to the present technology, the number of spaces between the heating members is reduced and the mounting components are less likely to overlap the spaces. Even if a width or an arrangement space of the mounting components may be altered, the compression bonding is performed easily and effectively. In other words, if the width or the arrangement space of the mounting component is altered, the heating members are not necessary to be replaced with different ones and productivity is improved.

The first heating member and the second heating member may be movable relative to the mounting components in the arrangement direction of the mounting components. According to such a configuration, if the width (a length in the arrangement direction) of the mounting component or the arrangement space is altered, the compression bonding is performed easily by moving the first heating member and the second heating member.

The substrate may have a rectangular shape and the mounting components may be arranged in one side direction of the substrate, and a total value of a length of the first heating member and a length of a second heating member in the one side direction of the substrate may be greater than a length of the substrate in the one side direction. According to such a configuration, even if the mounting components are arranged over an entire length of the substrate in the one side direction, the mounting components are thermally pressed and bonded surely by the first heating member and the second heating member.

Each of the length of the first heating member and the length of the second heating member in the one side direction of the substrate may be ⅔ of the length of the substrate in the one side direction or greater and equal to the length of the substrate in the one side direction or smaller.

In the configuration that the mounting components are arranged in the one side direction of the substrate, the width of the mounting component is generally set ⅔ of the length in the one side direction or smaller. Therefore, the width of the mounting component may not be greater than the length of the first heating member (or the second heating member) since the length of each of the first heating member and the second heating member is set ⅔ of the length of the substrate in the one side direction or greater. The first heating member or the second heating member may not be required to be changed according to the width of the mounting component.

Next, to solve the above problem, a method of manufacturing a mounting substrate includes a first thermal compression bonding process of pressing and heating a first mounting component group with a first heating member, the first mounting component group including one edge side mounting component that is arranged on one edge in an arrangement direction in which mounting components are arranged on a substrate and thermally pressing and bonding the first mounting component group on the substrate, and a second thermal compression bonding process of pressing and heating a second mounting component group with a second heating member, the second mounting component group including all the mounting components except for the first mounting component group and thermally pressing and bonding the second mounting component group on the substrate.

According to the present technology, the mounting components are thermally pressed by the two heating members (the first heating member and the second heating member). Therefore, compared to a configuration in which the mounting components are collectively and thermally pressed with one heating member, each of the pressing members has a smaller length and thermal strain is less likely to be caused in the heating member when heating. Compared to a configuration including heating members in a same number of the mounting components, the total number of the heating members is smaller and the number of spaces between the adjacent heating members is also smaller. To surely thermally press and the bond the mounting components, each heating member is necessary to be arranged such that the space between the adjacent heating members is not overlapped with the mounting component. According to the present technology, the number of spaces between the heating members is reduced and the arrangement of the heating members can be set easily. Therefore, even if a width or an arrangement space of the mounting components may be altered, the compression bonding is performed easily and effectively.

### Advantageous Effect of the Invention

According to the present invention, the heating member for performing thermal compression bonding is less likely to be elongated.

### BRIEF DESCRIPTION OF THE DRAWINGS

FIG. 1 is a schematic cross-sectional view illustrating a cross-sectional configuration of a liquid crystal display device according to a first embodiment of the present invention taken in a long-side direction.

FIG. 2 is a schematic cross-sectional view illustrating a cross-sectional configuration of a liquid crystal panel of FIG. 1.

FIG. 3 is a plan view illustrating mounting areas of drivers and a flexible printed circuit board on an array substrate included in the liquid crystal panel.

FIG. 4 is a cross-sectional view illustrating a flexible printed circuit board mounting process (a cross-sectional view taken along line IV-IV in FIG. 3).

FIG. 5 is a cross-sectional view illustrating a flexible printed circuit board mounting apparatus and a flexible printed circuit board mounting process.

FIG. 6 is a cross-sectional view illustrating a first thermal compression bonding process (a cross-sectional view taken along line VI-VI in FIG. 3).

FIG. 7 is a cross-sectional view illustrating comparative example.

FIG. 8 is a cross-sectional view illustrating a flexible printed circuit board mounting apparatus and a flexible printed circuit board mounting process according to a second embodiment.

FIG. 9 is a cross-sectional view illustrating a flexible printed circuit board mounting process according to modified example 1.

FIG. 10 is a cross-sectional view illustrating a flexible printed circuit board mounting process according to a modified example 2.

FIG. 11 is a cross-sectional view illustrating a flexible printed circuit board mounting process according to a modified example 3.

FIG. 12 is a cross-sectional view illustrating a flexible printed circuit board mounting process according to a modified example 4.

FIG. 13 is a cross-sectional view illustrating a cross-sectional view illustrating a flexible printed circuit board mounting process according to a modified example 5.

### MODE FOR CARRYING OUT THE INVENTION

### First Embodiment

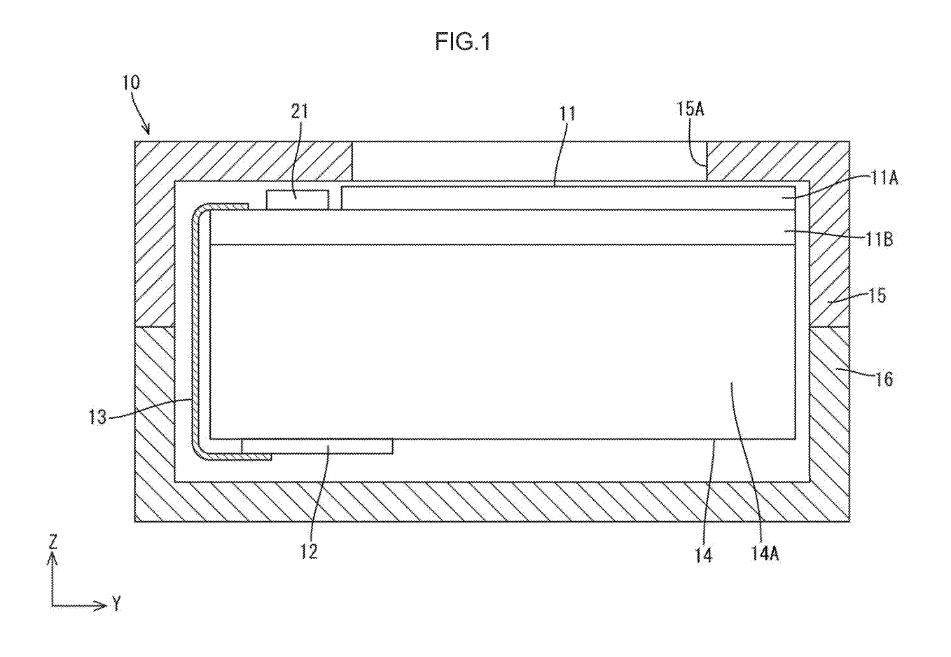

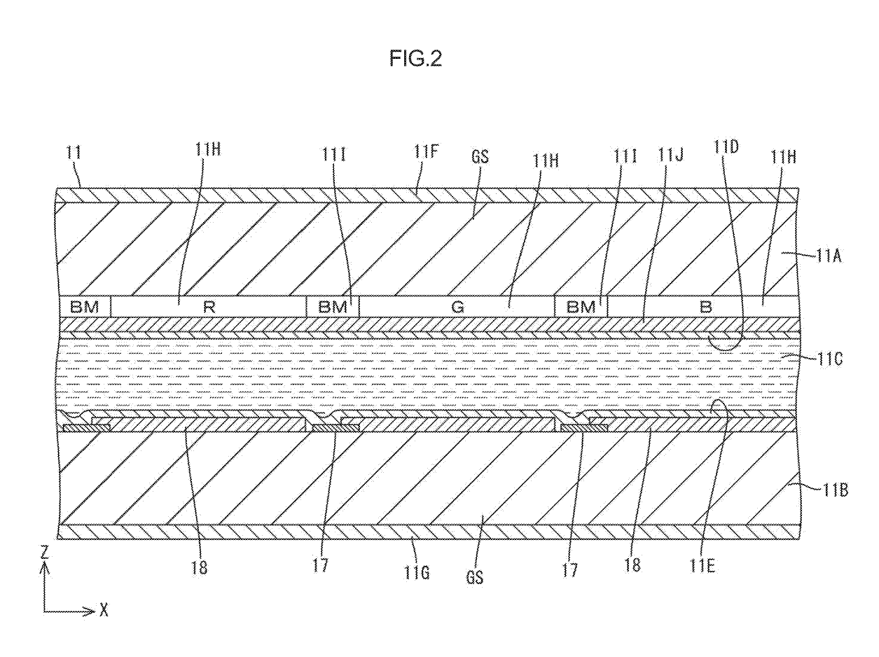

A first embodiment will be described with reference to FIGS. 1 to 7. In the present embodiment, a method of manufacturing a liquid crystal panel (mounting substrate) 11 included in a liquid crystal display device 10 and a flexible printed circuit board mounting apparatus 40 (a manufacturing apparatus) used in the manufacturing method will be described. X-axis, Y-axis and Z-axis may be indicated in the drawings. The axes in each drawing correspond to the respective axes in other drawings. The Z-axis direction that is a vertical direction at the time of manufacturing (and a thickness direction of the liquid crystal panel 11) is defined based on FIGS. 1 and 2. An upper side and a lower side in FIGS. 1 and 2 correspond to a front side and a back side of the device, respectively.

As illustrated in FIG. 1, a liquid crystal display device 10 includes the liquid crystal panel 11, a control circuit board 12 (an external signal source), a flexible printed circuit board 13, and a backlight unit 14 (a lighting device). Drivers 21 are mounted on the liquid crystal panel 11. The control circuit board 12 supplies various input signals from outside to the drivers 21. The flexible printed circuit board 13 electrically connects the liquid crystal panel 11 and the external control circuit board 12. The backlight unit 14 is an external light source that supplies light to the liquid crystal panel 11. The liquid crystal display device 10 further includes a pair of exterior components 15 and 16 that are front and rear components used in a pair to hold the liquid crystal panel 11 and the backlight unit 14 that are attached together. The exterior component 15 on the front has an opening 15A through which images displayed on the liquid crystal panel 11 are viewed from the outside. The liquid crystal display device 10 according to this embodiment may be used in various kinds of electronic devices (not illustrated) such as television, handheld terminals (including electronic books and PDAs), mobile phones (including smartphones), notebook computers (including tablet computers), digital photo frames, portable video game players, and electronic-ink papers.

The backlight unit 14 will be described. As illustrated in FIG. 1, the backlight unit 14 includes a chassis 14A, light sources (e.g., cold cathode fluorescent tubes, LEDs, organic ELs, which are not illustrated), an optical member. The chassis 14A has a box-like shape with an opening on the front (on a liquid crystal panel 11 side). The light sources are disposed inside the chassis 14A. The optical member, which is not illustrated, is arranged so as to cover the opening of the chassis 14A. The optical member has a function to convert light from the light sources into planar light.

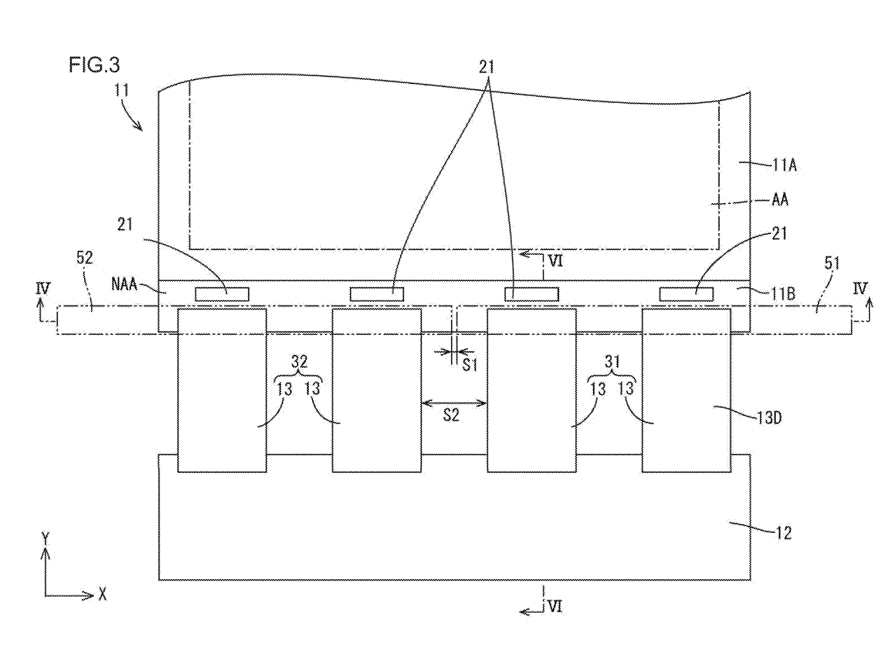

Next, the liquid crystal panel 11 will be described. As illustrated in FIG. 1, the liquid crystal panel 11 has a horizontally-long rectangular overall shape elongated in the Y-axis direction. As illustrated in FIG. 3, the liquid crystal panel 11 includes a display area (an active area) AA that is off centered toward one of ends of a long dimension thereof (the upper side in FIG. 3). The drivers 21 and the flexible printed circuit board 13 are arranged at the other end of the long dimension of the liquid crystal panel 11 (the lower side in FIG. 3). An area of the liquid crystal panel 11 outside the display area AA is a non-display area (non-active area) NAA in which images are not displayed and the non-display area includes a mounting area in which the drivers 21 and the flexible printed circuit board 13 are mounted. A short-side direction and a long-side direction of the liquid crystal panel 11 correspond to the X-axis direction and the Y-axis direction in each drawing. In FIG. 3, a chain line box slightly smaller than the CF substrate 11A indicates a boundary of the display area AA. An area outside the chain line is the non-display area NAA.

As illustrated in FIG. 2, the liquid crystal panel 11 includes a pair of transparent (having high transmissivity) substrates 11A and 11B (a first substrate and a second substrate), and a liquid crystal layer 11C between the substrates 11A and 11B. The liquid crystal layer 11C includes liquid crystal molecules having optical characteristics that vary according to application of electric field. The substrates 11A and 11B are bonded together with a sealing agent, which is not illustrated, with a cell gap therebetween. The cell gap corresponds to a thickness of the liquid crystal layer 11C. The substrates 11A, 11B include glass substrates GS made of alkali-free glass or quartz glass, and includes films that are layered on the glass substrates GS with the known photolithography method. The pair of substrates 11A, 11B includes a CF substrate 11A (an opposing substrate, a first substrate) on the front (on a front surface side) and an array substrate 11B (a component substrate, an active matrix substrate, a second substrate) on a back side (on a rear surface side). As illustrated in FIG. 1, the CF substrate 11A has a short-side dimension substantially same as that of the array substrate 11B and has a long-side dimension smaller than that of the array substrate 11B. The CF substrate 11A and the array substrate 11B are bonded together such that short-side edges (right-side edges in FIG. 1) thereof are aligned with each other.

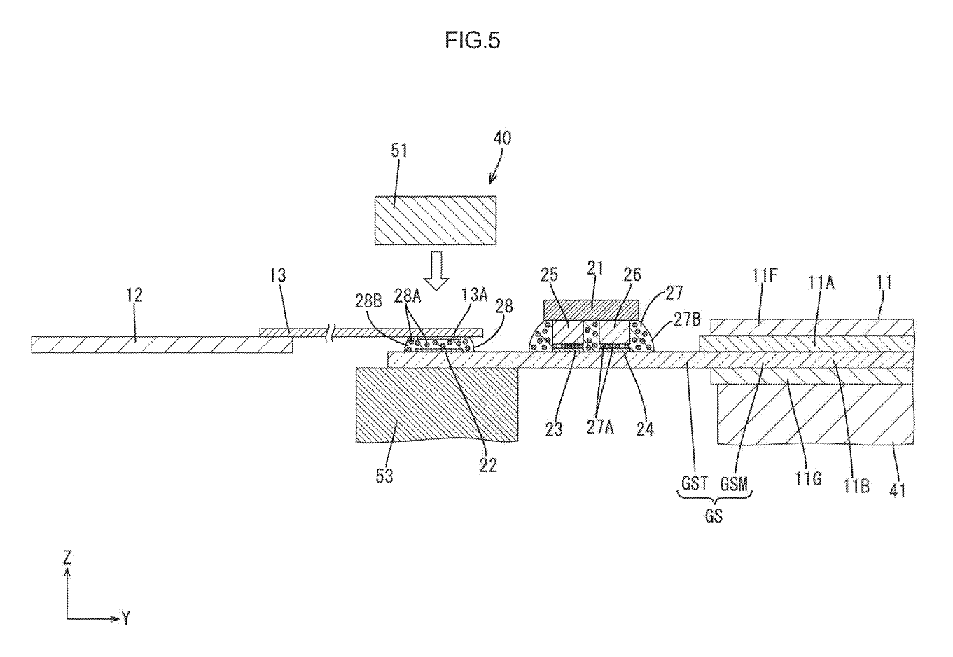

According to such a configuration, the CF substrate 11A and the array substrate 11B are not overlapped with each other in the other edge portions thereof in the long side direction (left-side edges in FIG. 1) over a certain area and the short-side edge portion of the array substrate 11B is exposed outside on the front and rear plate surfaces thereof. Thus, the exposed portion is a mounting area where the drivers 21 and the flexible printed circuit board 13 are mounted. Namely, the CF substrate 11A is bonded to the array substrate 11B such that the terminal portions 22 to 24 (see FIG. 5) that are to be electrically connected to the drivers 21 and the flexible printed circuit boards 13 are exposed. The glass substrate GS of the array substrate 11B includes a substrate main portion GSM where the CF substrate 11A and a polarizing plate 11G are bonded and a terminal forming portion GST that is not overlapped with the CF substrate 11A and the polarizing plate 11G and on which the terminals 22 to 24 are formed. Alignment films 11D and 11E are formed on inner surfaces of the substrates 11A and 11B, respectively, for aligning the liquid crystal molecules included in the liquid crystal layer 11C. Polarizing plates 11F and 11G are bonded to outer surfaces of the substrates 11A and 11B, respectively.

Next, components on the array substrate 11B and the CF substrate 11A in the display area AA will be described in detail. As illustrated in FIG. 2, a number of the TFTs (thin film transistors) 17 and a number of pixel electrodes 18 are arranged in a matrix on the inner surface of the array substrate 11B (the liquid crystal layer 11C side, the opposed surface side opposed to the CF substrate 11A). Furthermore, the gate lines and the source lines (both not illustrated) are arranged in a grid to surround the TFTs 17 and the pixel electrodes 18. Namely, the TFTs 17 and the pixel electrodes 18 are arranged at the respective intersections of the gate lines and the source lines and in a grid. The gate lines and the source lines are connected to gate electrodes and source electrodes of the TFTs 17, respectively. The pixel electrodes 18 are connected to drain electrodes of the TFTs 17. Each of the pixel electrodes 18 has a vertically long rectangular shape in a plan view. The pixel electrodes 18 are made of transparent electrode material such as indium tin oxide (ITO) and zinc oxide (ZnO). Furthermore, an auxiliary capacitor line (not illustrated) may be formed to be parallel to the gate lines and to cross the pixel electrodes 18.

As illustrated in FIG. 2, color filters 11H are formed on the CF substrate 11A. The color filters 11H include red (R), green (G), and blue (B) color portions are arranged in a matrix to overlap the pixel electrodes 18 on the array substrate 11B in a plan view. A light blocking layer 11I having a grid shape (a black matrix) is formed between the color portions included in the color filters 11H for reducing color mixture. The light blocking layer 11I is arranged to overlap the gate lines and the source lines in a plan view. A counter electrode 11J is formed in a solid pattern on surfaces of the color filters 11H and the light blocking layer 11I. The counter electrode 11J is opposed to the pixel electrodes 18 on the array substrate 11B. In the liquid crystal panel 11, the R (red) color portion, the G (green) color portion, the B (blue) color portion, and three pixel electrodes 18 opposed to the color portions form a display pixel that is a display unit. Each display pixel includes a red pixel including the R color portion, a green pixel including the G color portion, and a blue pixel including the B color portion. The color pixels are repeatedly arranged along a row direction (the X-axis direction) on a plate surface of the liquid crystal panel to form lines of pixels. The lines of pixels are arranged along the column direction (the Y-axis direction).

The components connected to the liquid crystal panel 11 will be described. As illustrated in FIG. 1, the control circuit board 12 is attached to the back surface of the chassis 14A of the backlight unit 14 (an outer surface on a side opposite from the liquid crystal panel 11 side) with a screw or other fixing member. The control circuit board 12 includes a substrate made of paper phenol or glass epoxy resin and electronic components mounted on the substrate for supplying various kinds of input signals to the drivers 21. The control circuit board 12 further includes predetermined traces (conductive lines), which are not illustrated, routed on the substrate. One of end portions (one end side) of the flexible printed circuit board 13 is electrically and mechanically connected to the control circuit board 12 via an anisotropic conductive film, which is not illustrated.

As illustrated in FIG. 3, the flexible printed circuit board 13 includes multiple flexible printed circuit boards (four in the present embodiment) that are arranged linearly along one side of the array substrate 11B. The flexible printed circuit board 13 includes a base member made of synthetic resin (e.g., polyimide resin) having an insulating property and flexibility. The flexible printed circuit board 13 includes traces (not illustrated) on the base member. One end portion, which is one of end portions of the flexible printed circuit board 13 with respect to the length direction thereof, is connected to the control circuit board 12 on the back surface of the chassis 14A. The other end portion of the flexible printed circuit board 13 is connected to the array substrate 11B of the liquid crystal panel 11. Namely, the flexible printed circuit board 13 is folded in the liquid crystal display device 10 such that a shape in a cross-sectional view is a U-like shape. The end portions of the flexible printed circuit board 13 with respect to the length direction include exposed portions of traces which form terminals (not illustrated). The terminals are electrically connected to the control circuit board 12 and the liquid crystal panel 11. According to the configuration, the input signals supplied by the control circuit board 12 are transmitted to the liquid crystal panel 11.

The driver 21 includes an LSI chip including a driver circuit therein. The driver 21 operates according to signals supplied by the control circuit board 12, which is a signal source, processes the input signals supplied by the control circuit board 12, which is a signal source, generates output signals, and sends the output signals to the display area AA of the liquid crystal panel 11. The LSI chip included in the driver 21 includes traces and components formed on a silicon wafer that contains silicon with high purity. As illustrated in FIG. 3, the driver 21 has a horizontally long rectangular shape in the plan view. The driver 21 is orientated such that a long-side direction thereof is along the short-side direction of the liquid crystal panel 11. The drivers 21 are directly mounted on the array substrate 11B in the non-display area NAA of the liquid crystal panel 11 with the COG (chip on glass) mounting technology.

As illustrated in FIG. 5, external connection terminals 22 are formed in the mounting area of the array substrate 11B in which the flexible printed circuit board 13 is mounted. The external connection terminals 22 receive supply of input signals from the flexible printed circuit board 13. Panel-side input terminals 23 and panel-side output terminals 24 are mounted in the mounting area of the array substrate 11B in which the drivers 21 are to be mounted. Input signals are supplied from the panel-side input terminals 23 to the drivers 21, and output signals from the drivers 21 are supplied to the panel-side output terminals 24. The external connection terminals 22 and the panel-side input terminals 23 are electrically connected to each other via relay traces (not illustrated).

An anisotropic conductive film 27 (ACF, anisotropic conductive material) is arranged on the panel-side input terminals 23 and the panel-side output terminals 24. The driver-side input terminals 25 of the drivers 21 are electrically connected to the panel-side input terminals 23 and the driver-side output terminals 26 are electrically connected to the panel-side output terminals 24 via conductive particles 27A. The anisotropic conductive film 27 includes the conductive particles 27A made of metal material and thermosetting resin 27B in which the conductive particles 27A are dispersed.

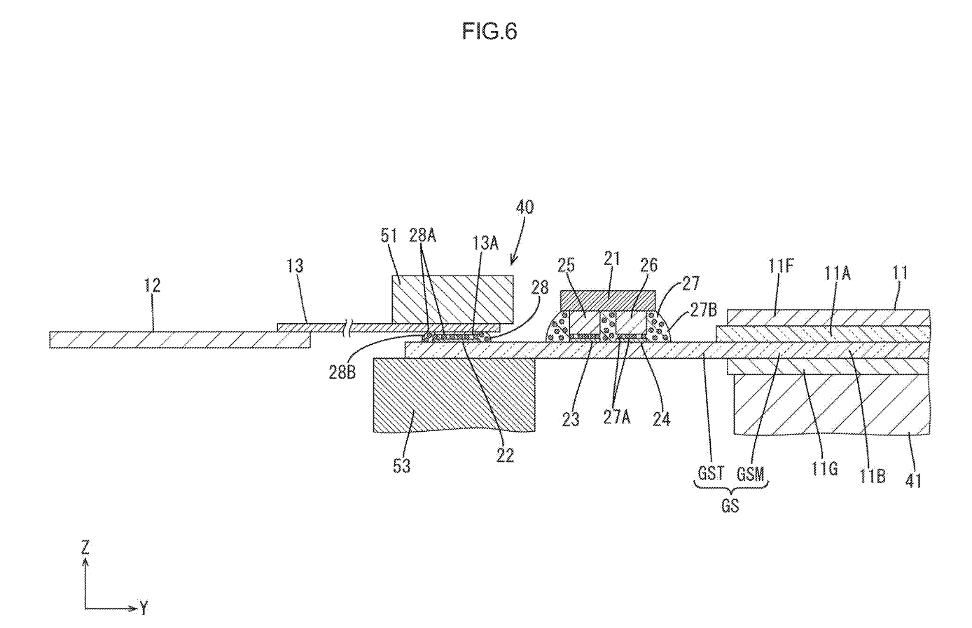

The external connection terminals 22 illustrated in FIG. 6 are connected to flexible printed circuit board side terminals 13A of the flexible printed circuit board 13 via the anisotropic conductive film 28. The anisotropic conductive film 28 includes the conductive particles 28A made of metal and thermosetting resin 28B (binder) in which the conductive particles 28A are dispersed. The external connection terminals 22 are electrically connected to the flexible printed circuit board side terminals 13A via the conductive particles 28A. Each of the conductive particles included in the anisotropic conductive films 27, 28 includes a metal core (for example, a core made of nickel coated with gold) that is covered with insulating film and the insulating film is broken or melted by heat or pressure in a thermal pressing, which will be described later.

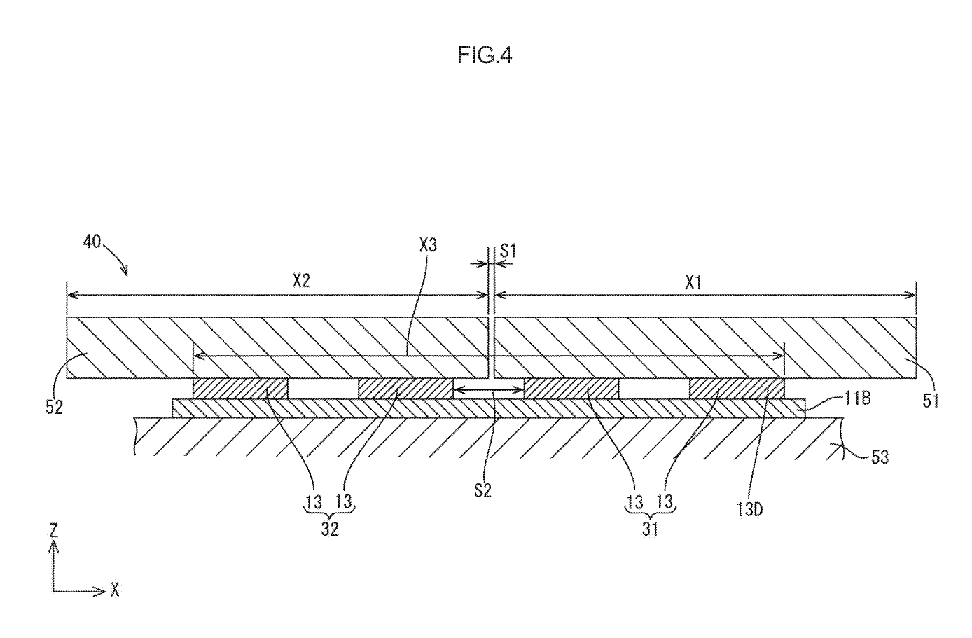

Next, a flexible printed circuit board mounting apparatus 40 (a manufacturing apparatus) for mounting the flexible printed circuit board 13 (the mounting component, FPC) on the array substrate 11B (the substrate) will be described. The flexible printed circuit board mounting apparatus 40 is a film on glass (FOG) apparatus. As illustrated in FIGS. 4 and 5, the flexible printed circuit board mounting apparatus 40 includes a substrate support member 41, a first FPC-side pressing member, 51 (a first heating member, a pressing head), a second FPC-side pressing member 52 (a second heating member, a pressing head), and a substrate-side pressing member 53 (a substrate-side heating member).

The substrate support member 41 supports the substrate main portion GSM of the glass substrate GS of the array substrate 11B from the rear side (the opposite side from the drivers 21). The substrate support member 41 includes holding means such as vacuum sucking and holds the substrate main portion GSM. The substrate support member 41 is a movable stage that is movable in a plate surface direction (in the X-axis direction and the Y-axis direction) and in a thickness direction (the Z-axis direction) of the liquid crystal panel 11 and also rotatable around the Z-axis. With such a configuration, one end portion (a portion to be connected to the flexible printed circuit board 13) of the liquid crystal panel 11 placed on the substrate support member 41 can be moved between the first FPC-side pressing member 51 (or the second FPC-side pressing member 52) and the substrate-side pressing member 53.

The substrate-side pressing member 53 supports a portion of the array substrate 11B where the external connection terminals 22 are formed (a flexible printed circuit board 13-side outer peripheral edge portion) from the rear side. As illustrated in FIG. 4, the substrate-side pressing member 53 has a length in the X-axis direction longer than the length of the array substrate 11B in the X-axis direction. The first FPC-side pressing member 51 and the second FPC-side pressing member 52 are movable in the Z-axis direction by moving means (lifting/lowering means) such as a motor or cylinder. Each of the first FPC-side pressing member 51, the second FPC-side pressing member 52, and the substrate-side pressing member 53 includes heat supply means (heating means) such as a heater. According to such a configuration, the first FPC-side pressing member 51 (or the second FPC-side pressing member 52) and the substrate-side pressing member 53 hold the flexible printed circuit board 13 and the array substrate 11B therebetween with pressing and heating (thermal compression bonding).

As illustrated in FIG. 4, in the present embodiment, four flexible printed circuit boards 13 are arranged in the short-side direction of the rectangular array substrate 11B (in one side direction, the X-axis direction). Each of the first FPC-side pressing member 51 and the second FPC-side pressing member 52 has a rectangular shape elongated in the X-axis direction. The first FPC-side pressing member 51 thermally presses two flexible printed circuit boards 13 on one edge side in the X-axis direction (on the right side in FIG. 4) (a first mounting component group 31 including the flexible printed circuit board 13D on the one edge). The second FPC-side pressing member 52 thermally presses two flexible printed circuit boards on another edge side in the X-axis direction (on the left side) (a second mounting component group 32). Namely, the second FPC-side pressing member 52 thermally presses all the flexible printed circuit boards 13 except for the first mounting component group 31.

As illustrated in FIG. 4, the length X1 of the first FPC-side pressing member 51 in the X-axis direction is set such that the first FPC-side pressing member 51 can press the two flexible printed circuit boards 13 at the same time. The length X1 of the first FPC-side pressing member 51 is set ⅔ of a length X3 of the array substrate 11B in the X-axis direction or greater and equal to or lower than the length X3. A length X2 of the second FPC-side pressing member 52 in the X-axis direction is set such that the second FPC-side pressing member 52 can press the two flexible printed circuit boards 13 at the same time. The length X2 of the second FPC-side pressing member 52 is set ⅔ of the length X3 of the array substrate 11B or greater and equal to or lower than the length X3.

A total value of the length of the first FPC-side pressing member 51 and the length of the second FPC-side pressing member 52 is set greater than the length of the array substrate 11B. The first FPC-side pressing member 51 and the second FPC-side pressing member 52 are arranged next to each other in the X-axis direction with a space S1 therebetween and the space S1 is smaller than a space S2 between the adjacent flexible printed circuit boards 13. According to such a configuration, the flexible printed circuit board 13 is not overlapped with the space S1. In the present embodiment, the flexible printed circuit boards 13 are arranged in the X-axis direction at equal intervals. However, it is not limited thereto. As illustrated in FIG. 5, lengths of the first FPC-side pressing member 51, the second FPC-side pressing member 52, and the substrate-side pressing member 53 in the Y-axis direction are greater than that of the anisotropic conductive film 28 in the Y-axis direction.

Next, a method of manufacturing the liquid crystal panel 11 (the array substrate 11B) will be described. The method of manufacturing the liquid crystal panel 11 includes at least a structured components forming process, a substrate bonding process, a polarizing plate attachment process, a driver mounting process, and a flexible printed circuit board mounting process. In the structured components forming process, metal films and insulation films are layered on an inner plate surface of each glass substrate GS of the CF substrate 11A and the array substrate 11B with the known photolithography method to form various structured components. In the substrate bonding process, the glass substrate GS of the CF substrate 11A and the glass substrate GS of the array substrate 11B are bonded together. In the polarizing plate attachment process, the polarizing plates 11F, 11G are attached to the respective outer plate surfaces of the glass substrates. In the driver mounting process, the drivers 21 are mounted on the glass substrate GS of the array substrate 11B via the anisotropic conductive film 27 with using a driver mounting apparatus. In the flexible printed circuit board mounting process, each flexible printed circuit board 13 is mounted on the liquid crystal panel 11.

Hereinafter, the flexible printed circuit board mounting process using the flexible printed circuit board mounting apparatus 40 will be described in detail. The flexible printed circuit board mounting process further includes at least an anisotropic conductive film applying process, a provisional compression bonding process, and a compression bonding process. In the anisotropic conductive film applying process, the anisotropic conductive film 28 is applied on the glass substrate GS of the array substrate 11B. In the provisional compression bonding process, the flexible printed circuit boards 13 are placed on the anisotropic conductive film 28 and provisionally pressed. In the compression bonding process, the flexible printed circuit boards 13 are pressed and bonded. The compression bonding process includes a first thermal compression bonding process and a second thermal compression bonding process.

As illustrated in FIG. 5, in the compression bonding process, the liquid crystal panel 11 is placed on the substrate support member 41. In such a state, the glass substrate GS of the array substrate 11B is supported by the substrate support member 41 from the rear side and is strongly held by the substrate support member 41 due to vacuum contact with the polarizing plate 11G attached on the outer plate surface of the glass substrate GS. Next, the substrate support member 41 is moved such that the anisotropic conductive film 28 is located between the first FPC-side pressing member 51 (and the second FPC-side pressing member 52) and the substrate-side pressing member 53. Thereafter, the first thermal compression bonding process and the second thermal compression bonding process will be performed simultaneously.

(First Thermal Compression Bonding Process)

As illustrated in FIGS. 4 and 6, in the first thermal compression bonding process, the first FPC-side pressing member 51 is lowered and holds the outer peripheral edge portion of the array substrate 11B between the first FPC-side pressing member 51 and the substrate-side pressing member 53. Accordingly, the first FPC-side pressing member 51 is in contact with the two flexible printed circuit boards 13 (the first mounting component group 31) and the substrate-side pressing member 53 is in contact with the rear surface of the array substrate 11B. Then, the first FPC-side pressing member 51 and the substrate-side pressing member 53 are supplied with heat, and the heat is transferred to the thermosetting resin 28B contained in the anisotropic conductive film 28 and promotes thermosetting of the thermosetting resin 28B.

If the first FPC-side pressing member 51 is further lowered from the contact state, the anisotropic conductive film 28 is pressed and pressure force is applied thereto. Lowering of the first FPC-side pressing member 51 is stopped if the first FPC-side pressing member 51 reaches a certain height position. Then, the application of pressure force and supply of heat to the anisotropic conductive film 28 will still continue for a certain period. Accordingly, as illustrated in FIG. 6, the flexible printed circuit board-side terminals 13A on the flexible printed circuit board 13 side are electrically connected to the external connection terminals 22 on the array substrate 11B side via the conductive particles 28A contained in the anisotropic conductive film 28, and the thermosetting resin 28B included in the anisotropic conductive film 28 is thermally cured, and the flexible printed circuit boards 13 (the first mounting component group 31) are thermally pressed and bonded (compression bonding) on the array substrate 11B.

(Second Thermal Compression Bonding Process)

As illustrated in FIG. 4, in the second thermal compression bonding process, the second FPC-side pressing member 52 is lowered and holds the outer peripheral edge portion of the array substrate 11B between the second FPC-side pressing member 52 and the substrate-side pressing member 53. Accordingly, the second FPC-side pressing member 52 is in contact with the two flexible printed circuit boards 13 (the second mounting component group 32) and the substrate-side pressing member 53 is in contact with the rear surface of the array substrate 11B. Then, the second FPC-side pressing member 52 and the substrate-side pressing member 53 are supplied with heat, and the heat is transferred to the thermosetting resin 28B contained in the anisotropic conductive film 28 and promotes thermosetting of the thermosetting resin 28B.

If the second FPC-side pressing member 52 is further lowered from the contact state, the anisotropic conductive film 28 is pressed and pressure force is applied thereto. Lowering of the second FPC-side pressing member 52 is stopped if the second FPC-side pressing member 52 reaches a certain height position. Then, the application of pressure force and supply of heat to the anisotropic conductive film 28 will still continue for a certain period. Accordingly, the flexible printed circuit board-side terminals 13A on the flexible printed circuit board 13 side are electrically connected to the external connection terminals 22 on the array substrate 11B side via the conductive particles 28A contained in the anisotropic conductive film 28, and the thermosetting resin 28B included in the anisotropic conductive film 28 is thermally cured, and the flexible printed circuit boards 13 (the second mounting component group 32) are thermally pressed and bonded (compression bonding) on the array substrate 11B.

After completion of the compression bonding of the flexible printed circuit boards 13, the supply of heat from the first FPC-side pressing member 51, the second FPC-side pressing member 52, and the substrate-side pressing member 53 is stopped and the first FPC-side pressing member 51 and the second FPC-side pressing member 52 are lifted upward in the Z-axis direction to be away from the flexible printed circuit boards 13. In the compression bonding process, the first FPC-side pressing member 51 (or the second FPC-side pressing member 52) and the substrate-side pressing member 53 supply heat such that temperature of a connection surface of the flexible printed circuit board-side terminals 13A and the external connection terminals 22 is from 80° C. to 150° C. and apply a load of 100N to 450N to the terminal forming portion GST of the array substrate 11B.

Next, advantageous effects of the present embodiment will be described. According to the present embodiment, the multiple flexible printed circuit boards 13 are thermally pressed by the two pressing members (the first FPC-side pressing member 51 and the second FPC-side pressing member 52). Therefore, compared to a configuration in which the flexible printed circuit boards 13 are collectively and thermally pressed with one pressing member, each of the pressing members has a smaller length and thermal strain is less likely to be caused in the pressing member when heating (warping of the pressing member). With shorter pressing members, the flexible printed circuit board 13 is adjusted easily such that an upper surface of the flexible printed circuit board 13 is parallel to the lower surface (a contact surface to be in contact with the flexible printed circuit board) of the pressing member and the pressing member is easily replaced with a different one.

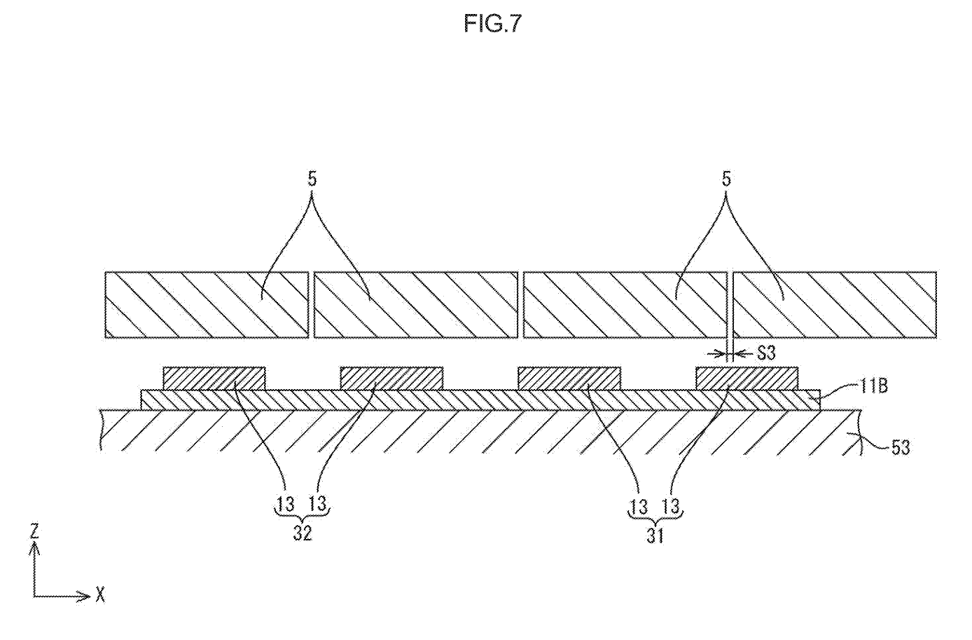

Compared to a configuration including pressing members 5 (heating members) in a same number of the flexible printed circuit boards 13 (refer comparative example in FIG. 7), the total number of the pressing members is smaller and the number of spaces between the adjacent pressing members is also smaller in the present embodiment. It is preferable that the pressing member is in contact with an entire area of the flexible printed circuit board-side terminals 13A and press and heat the entire area to thermally press and bond the flexible printed circuit boards 13 surely. To surely achieve this, each pressing member is necessary to be arranged such that the space between the adjacent pressing members is not overlapped with the flexible printed circuit board 13. In Comparative Example in FIG. 7, a space S3 between the adjacent pressing members 5 overlaps the flexible printed circuit board 13 and the overlapped portion of the flexible printed circuit board 13 is not thermally pressed and bonded effectively. In the present embodiment, the number of spaces between the pressing members is reduced and the flexible printed circuit boards 13 are less likely to overlap the spaces. Therefore, even if a width or an arrangement space of the flexible printed circuit boards 13 may be altered, the compression bonding is performed easily and effectively. In other words, if the width or the arrangement space of the flexible printed circuit boards 13 is altered, the pressing members (the first FPC-side pressing member and the second FPC-side pressing member) are not necessary to be replaced with different ones and productivity is improved.

In the present embodiment, the array substrate 11B is rectangular and the flexible printed circuit boards 13 are arranged along one side direction of the array substrate 11B. In the one side direction of the array substrate 11B, a total of the length X1 of the first FPC-side pressing member 51 and the length X2 of the second FPC-side pressing member 52 is greater than the length X3 of the array substrate 11B in the one side direction. According to such a configuration, even if the flexible printed circuit boards 13 are arranged over an entire length of the array substrate 11B in the one side direction (the X-axis direction), all the flexible printed circuit boards 13 are thermally pressed and bonded surely by the first FPC-side pressing member 51 and the second FPC-side pressing member 52. In the present embodiment, the first FPC-side pressing member 51 and the second FPC-side pressing member 52 are arranged over an entire length of the array substrate 11B in the one side direction (more specifically, the entire length of the array substrate 11B except for the portion overlapping the space S1 between the first FPC-side pressing member 51 and the second FPC-side pressing member 52). Therefore, the width of each flexible printed circuit board 13 (the length in the X-axis direction) or the arrangement space between the flexible printed circuit boards 13 may be altered as long as the flexible printed circuit board 13 is not overlapped with the space S1.

The length of the first FPC-side pressing member 51 and the length of the second FPC-side pressing member 52 in the one side direction of the array substrate 11B is set ⅔ of the length X3 of the array substrate 11B in the one side direction or greater and the length X3 of the array substrate 11B in the one side direction or smaller.

The width (the length in the one side direction) of each flexible printed circuit board 13 is set based on the length of the array substrate 11B in the configuration that the flexible printed circuit boards 13 are arranged in the one side direction of the array substrate 11B. Generally, the width of the flexible printed circuit board 13 is set ⅔ of the length in the one side direction or smaller. Therefore, the width of the flexible printed circuit board 13 may not be greater than the length of the first FPC-side pressing member 51 (or the second FPC-side pressing member 52) since the length of each of the first FPC-side pressing member 51 and the second FPC-side pressing member 52 is set ⅔ of the length of the array substrate 11B in the one side direction. The first FPC-side pressing member 51 or the second FPC-side pressing member 52 may not be required to be changed according to the width of the flexible printed circuit board 13.

### Second Embodiment

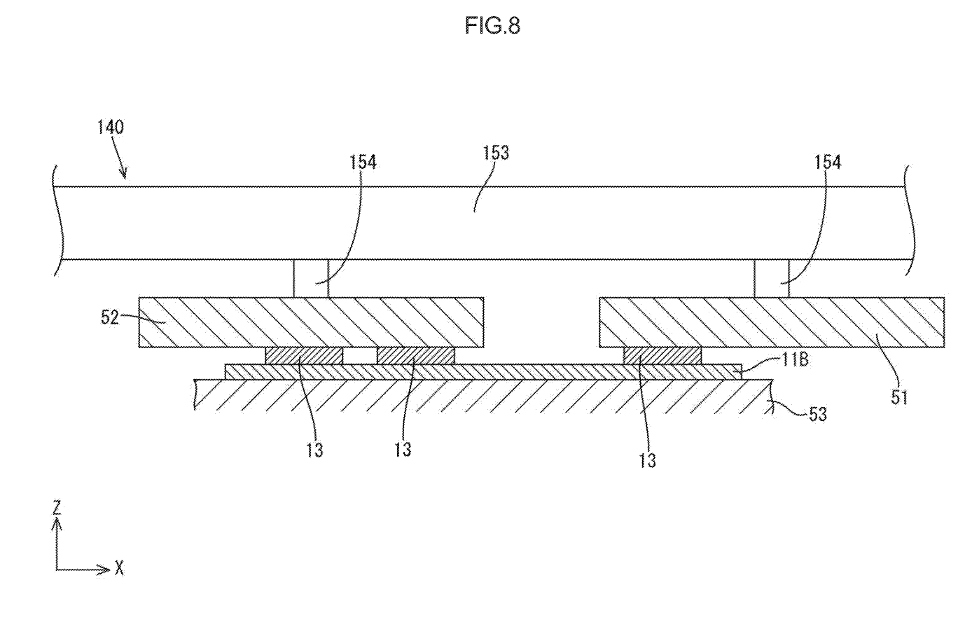

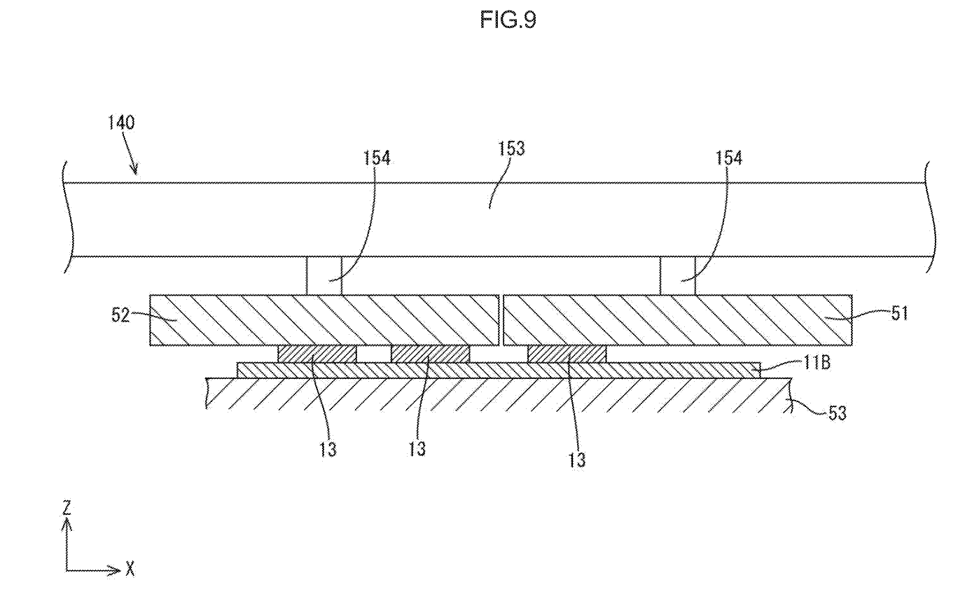

Next, a second embodiment of the present invention will be described with reference to FIGS. 8 to 13. In the second embodiment, a flexible printed circuit board mounting apparatus has a configuration different from that in the above embodiment. Same parts as those in the above embodiment are provided with same numerals or symbols and will not be described. A flexible printed circuit board mounting apparatus 140 includes a moving device 153 that moves the first FPC-side pressing member 51 and the second FPC-side pressing member 52 in the X-axis direction (an arrangement direction in which the flexible printed circuit boards 13 are arranged).

The moving device 153 may include driving means (such as a motor), which is not illustrated, and a slide rail extending in the X-axis direction and the moving device 153 can move the first FPC-side pressing member 51 and the second FPC-side pressing member 52 in the X-axis direction. According to such a configuration, the first FPC-side pressing member 51 and the second FPC-side pressing member 52 are relatively movable with respect to the flexible printed circuit boards 13 in the X-axis direction. The first FPC-side pressing member 51 and the second FPC-side pressing member 52 are mounted in the moving device 153 via a lifting/lowering device 154 (a cylinder or a motor) and are movable in the Z-axis direction with respect to the moving device 153. The configuration of the moving device 153 is not limited to the above one but may be altered if necessary.

In the present embodiment, if the width of each of the flexible printed circuit boards 13 (the length in the arrangement direction) or the arrangement space may be altered, the first FPC-side pressing member 51 and the second FPC-side pressing member 52 can be moved to the respective appropriate positions to easily deal with the change. For example, as illustrated in FIG. 8, in a configuration including three flexible printed circuit boards 13, one of the three flexible printed circuit boards 13 is pressed by the first FPC-side pressing member 51 and two of the three flexible printed circuit boards 13 are pressed by the second FPC-side pressing member 52. As illustrated in FIG. 8, if the space between the flexible printed circuit boards 13 is altered, the first FPC-side pressing member 51 is moved in the X-axis direction by the moving device 153 to press the flexible printed circuit boards 13 surely.

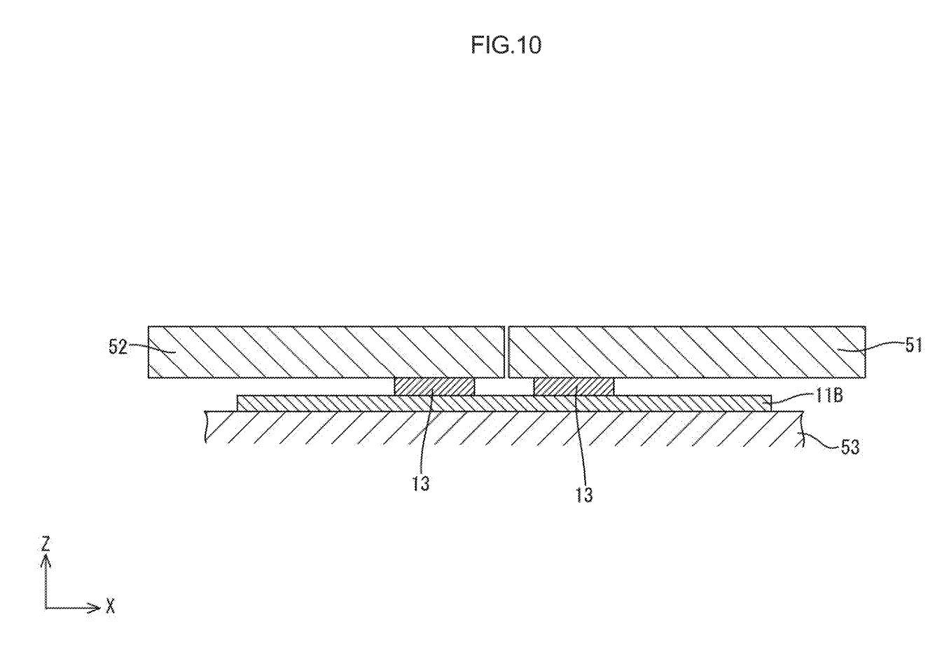

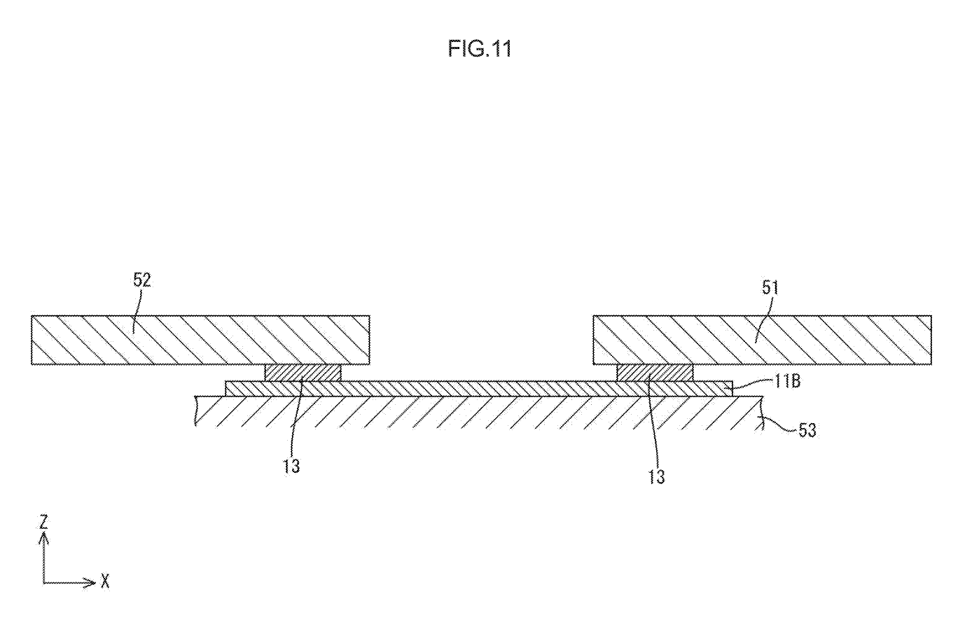

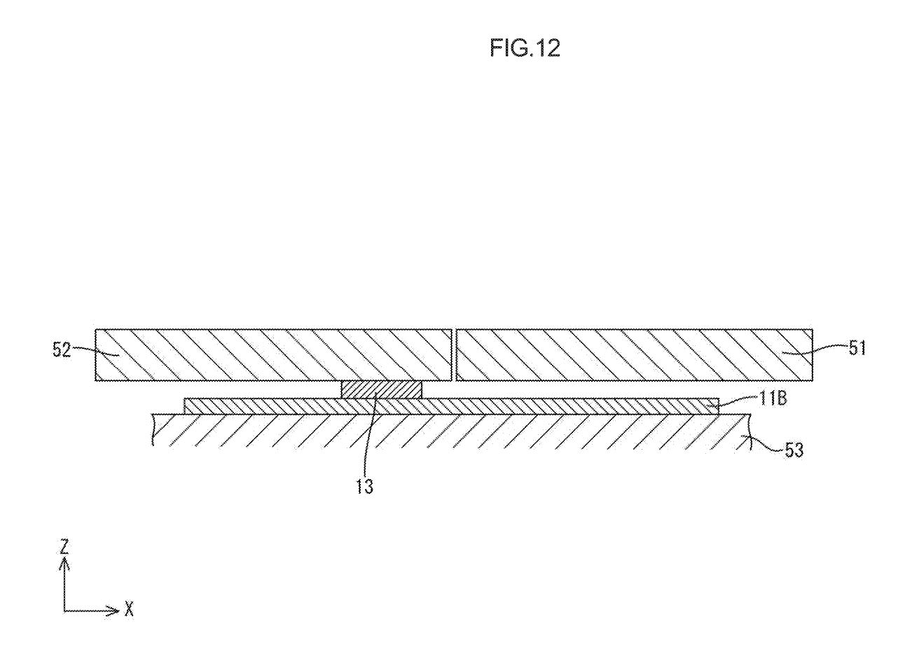

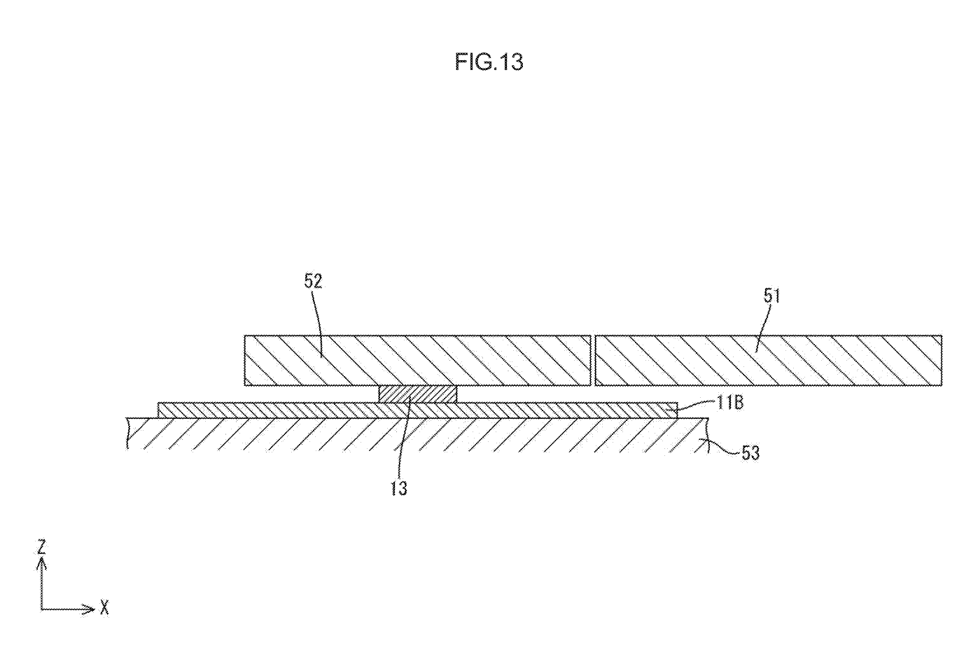

In the present embodiment, even if the number of the flexible printed circuit boards 13 is altered, the flexible printed circuit boards 13 can be surely pressed. For example, as illustrated in FIGS. 10 and 11, if the space between the two flexible printed circuit boards 13 is altered, the flexible printed circuit boards 13 can be surely pressed. As illustrated in FIGS. 12 and 13, if a mounting position of the flexible printed circuit 13 is altered, the flexible printed circuit board 13 can be surely pressed.

The first FPC-side pressing member 51 and the second FPC-side pressing member 52 are moved to be close to each other by the moving device 153 to have a space of 10 mm or less therebetween. They can be moved close to each other with a smallest space of approximately 1 mm. The space between the first FPC-side pressing member 51 and the second FPC-side pressing member 52 can be reduced further by arranging the traces for the heater included in the pressing members 51, 52 on surfaces opposite from the opposing surfaces thereof.

### OTHER EMBODIMENTS

The present invention is not limited to the embodiments, which have been described using the foregoing descriptions and the drawings. For example, embodiments described below are also included in the technical scope of the present invention.

(1) In the above embodiments, the array substrate 11B (the glass substrate GS) is used as the substrate. However, it is not limited thereto and the control circuit board 12 may be used as the substrate.

(2) In the above embodiments, the flexible printed circuit board 13 is used as the mounting component. However, it is not limited thereto and the driver 21 may be used as the mounting component.

(3) The number of the first mounting component group 31 is not necessarily limited that in the above embodiments but may be altered. The first mounting component group 31 is referred to as the mounting component that is pressed and bonded by the first FPC-side pressing member 51 and the number of the first mounting component group 31 is at least one or more.

(4) The second mounting component group 32 is referred to as the mounting component that is pressed and bonded by the second FPC-side pressing member 52 and the number of the second mounting component group 32 is at least one or more and may be altered, if necessary.

(5) In the above embodiments, the flexible printed circuit boards 13 are arranged along the short-side direction of the array substrate 11B. However, it is not limited thereto and the flexible printed circuit boards 13 may be arranged along the long-side direction of the array substrate 11B.

(6) In the above embodiments, the first thermal compression bonding process and the second thermal compression bonding process are performed simultaneously. However, it is not limited thereto and the second thermal compression bonding process may be performed after the first thermal compression bonding process.

(7) In the above embodiments, the substrate-side pressing member 53 includes the heating means. However, it is not limited thereto and the substrate-side pressing member 53 at least has a function of supporting the array substrate 11B from the rear side in the thermal compression bonding. The substrate-side pressing member 53 may be included integrally with the substrate support member 41.

(8) In the second embodiment, the first FPC-side pressing member 51 (and the second FPC-side pressing member 52) is moved in the X-axis direction relative to the flexible printed circuit board 13 by the moving device 153. However, it is not limited thereto and the array substrate 13B may be moved in the X-axis direction by the substrate support member 41 to move the first FPC-side pressing member 51 (and the second FPC-side pressing member 52) in the X-axis direction relative to the flexible printed circuit board 13.

### EXPLANATION OF SYMBOLS

11: liquid crystal panel (mounting substrate), 11B: array substrate (substrate), 13: flexible printed circuit board (mounting component), 31: first mounting component group, 32: second mounting component group, 40: flexible printed circuit board mounting apparatus (manufacturing apparatus), 51: first FPC-side pressing member (first heating member), 52: second FPC-side pressing member (second heating member), X1: length of the first FPC-side pressing member (length of the first heating member), X2: length of the second FPC-side pressing member (length of the second heating member), X3: length of the array substrate (length of the substrate in one side direction)

1. A mounting substrate manufacturing apparatus comprising:
a first heating member configured to press and heat a first mounting component group including one edge side mounting component that is arranged on one edge in an arrangement direction in which mounting components are arranged on a substrate and thermally press and bond the first mounting component group on the substrate; and
a second heating member arranged next to the first heating member in the arrangement direction and configured to press and heat a second mounting component group including all the mounting components except for the first mounting component group and thermally press and bond the second mounting component group on the substrate.

2. The mounting substrate manufacturing apparatus according to claim 1, wherein the first heating member and the second heating member are movable relative to the mounting components in the arrangement direction of the mounting components.

3. The mounting substrate manufacturing apparatus according to claim 1, wherein
the substrate has a rectangular shape and the mounting components are arranged in one side direction of the substrate, and
a total value of a length of the first heating member and a length of a second heating member in the one side direction of the substrate is greater than a length of the substrate in the one side direction.

4. The mounting substrate manufacturing apparatus according to claim 3, wherein
each of the length of the first heating member and the length of the second heating member in the one side direction of the substrate is ⅔ of the length of the substrate in the one side direction or greater and equal to the length of the substrate in the one side direction or smaller.

5. A method of manufacturing a mounting substrate comprising:
a first thermal compression bonding process of pressing and heating a first mounting component group with a first heating member, the first mounting component group including one edge side mounting component that is arranged on one edge in an arrangement direction in which mounting components are arranged on a substrate and thermally pressing and bonding the first mounting component group on the substrate; and
a second thermal compression bonding process of pressing and heating a second mounting component group with a second heating member, the second mounting component group including all the mounting components except for the first mounting component group and thermally pressing and bonding the second mounting component group on the substrate.
